(19) United States
(12) Patent Application Publication
(10) Pub. No.: US 2003/0051991 A1
(43) Pub. Date: Mar. 20, 2003

(54) Self-sustaining equipment for the production of a clean combustible gas via underliquid electric arcs between nonconsumable electrodes

(76) Inventor: Ruggero Maria Santilli, Palm Harbor, FL (US)

Correspondence Address: MASON & ASSOCIATES, PA, 17757 US HWY 19 N., SUITE 500, CLEARWATER, FL, 33764, US

(21) Appl. No.: 09/952,637

(22) Filed: Sep. 14, 2001

(51) Int. Cl. H01L 35/34

(52) U.S. Cl. 204/164; 136/205; 136/201

(57) ABSTRACT

The invention relates to a novel self-sustaining method for the clean production of energy based on supplying into a submerged electric arc between carbon-base electrodes or through a plasma created by an arc between carbon-base or metal-base electrodes the element which is missing for any given feedstock to achieve such a mixture of mostly ionized H, C and O atoms in the arc plasma and to contain equal moles of C and O as necessary to create CO and moles of H2, irrespective of whether the number of moles of H2 is larger, equal or smaller than that of CO. It is emphasized that this abstract is provided to comply with the rules requiring an abstract that will allow a searcher or other reader to quickly ascertain the subject matter of the technical disclosure. It is submitted with the understanding that it will not be used to interpret or limit the scope of meaning of the claims.

Numerous patented and non-patented equipment exist for the production of combustible gases by underliquid electric arcs between at least one carbon-base electrode, such as the combustible gas disclosed in U.S. Pat. No. 603,058 to H. Eldridge, the combustible gas disclosed in U.S. Pat. Nos. 5,159,900 and 5,417,817 to W. A. Dammann and D. Wallman, respectively, the combustible gas known as “AquaFuel™” disclosed in U.S. Pat. Nos. 5,435,274, 5,692,459, 5,792,325 to W. H. Richardson, Jr., the combustible gas known as “MagneGas™” discovered by R. M. Santilli (see the monograph described below and U.S. Pat. No. 6,183,604).

In all the above methods, the combustible gas is produced via an electric arc between a pair of electrodes of which at least one is made of carbonaceous material. The arc vaporizes the liquid and decomposes the liquid vapor in ways depending on the used method. The same electric arc also vaporizes the carbon-base electrode, by forming a plasma of mostly ionized atoms of H, O and C at about 10,000 degrees F. Besides a number of secondary thermochemical reactions depending on the selected method, the affinity between C and O dominates over the corresponding affinities between H and C or H and O, resulting in the formation of CO. The residual H atoms then generally combine to form the hydrogen gas H2. The extremely high magnetic fields existing at atomic distances of the electric arc deform the orbitals of the atomic components of the combustible gas resulting in the new chemical species of “magnecules” as more appropriately described in the monograph: R. M. Santilli, Foundations of Hadronic Chemistry with Applications to New Clean Energies and Fuels, Kluwer Academic Publishers, Boston-Dordrecht-London, 2001, ISBN number 1-4020-0087-1, which is herein incorporated by reference.

When the electric arc occurs within pure water as feedstock, thermochemistry teaches that the resulting gas is essentially composed of 50% H2 and 50% CO plus traces of CO2, H2O and O2 depending on the assumed method. When the electric arc occurs within antifreeze waste, chemical analyses have established that the combustible gas is composed of 50% H2 and 47% CO, the balance being composed by methane, ethane, water vapor, carbon dioxide and oxygen, all generally bonded into magnecular clusters.

It should be noted that nonconsumable electrodes, such as those made of tungsten, are industrially unacceptable since they imply severe limitations in the electric power, with consequential severe limitations in the size of the equipment and its output of combustible gas. For instance, an underliquid arc operated by a 50 Kwh power unit can indeed have one electrode made of tungsten, the anode, while the cathode must necessarily be of carbon-base material because tungsten would melt in seconds. This is due to the fact that the anode is negatively charged, thus releasing the electrons of the DC arc current, which electrons then hit the positively charged cathode, resulting in an evident larger temperature of the cathode with respect to the anode. The same arrangement of one consumable carbon-base cathode and a permanent tungsten anode cannot operate at more than 1,000 A because the tungsten anode itself would melt in seconds under larger electric currents.

The combustible gases are generally clean because they generally contain no hydrocarbons, while CO is part of the combustible gas itself, rather than a byproduct of the combustion as it is the case for fossil fuels. Therefore, under ideal condition of perfect combustion, the exhaust of the combustible gases has no measurable hydrocarbons or toxic substances such as CO, while being essentially constituted by water vapor, oxygen, carbon dioxide and atmospheric gases. Therefore, the combustible gases addressed in this invention indeed do have a large ecological importance.

THE FIRST INSUFFICIENCY OF THE ABOVE IDENTIFIED METHODS is that the carbon-base electrode is rapidly consumed as a necessary condition to provide the carbon necessary for the very formation of the combustible gas. For instance, a DC electric arc within water or antifreeze powered by a 50 Kwh DC generator unit can be continuously sustained between 1 inch diameter carbon electrodes. However, the latter consume at the rate of about 1 inch/min, resulting in a daily consumption of about 500 linear inches of 1 inch diameter carbon rods per day. The rate of consumption of the same electrodes with 100 Kwh power units is more than double the preceding one for 50 Kwh for various physical and chemical reasons.

THE SECOND INSUFFICIENCY OF THE ABOVE IDENTIFIED METHODS is that the cost of carbon-base electrode is so high to prevent the combustible gas to be cost competitive with respect to fossil fuels. As an illustration, the indicated reactor powered by 50 Kwh and 1 inch carbon electrodes produces a maximum of 500 standard cubic feet (scf) of combustible gas per hour with a consumption of 60 inches of electrodes per hour corresponding to five 12 inch long carbon rods. The latter cost is about $ 1.50/12 inch rod. Therefore, the cost of carbon per scf of the gas produced is of 5×$ 1.50/500 scf=$ 0.015/scf plus the cost of electricity and other costs. As a result, the cost of carbon prevents, alone, the combustible gases to be cost competitive over natural gas since the latter sells at about $ 0.006/scf, namely, at about half the mere cost of carbon to produce said combustible gases.

THE THIRD INSUFFICIENCY OF THE ABOVE IDENTIFIED METHODS is that the cost of the electricity needed for its production prevents, alone, the produced combustible gases to be cost competitive with respect to fossil fuels. Again with reference to the above identified equipment, the production of 500 scf of combustible gas from 50 Kwh implies the use of 100 W/scf, that is a cost of $ 0.008/scf computed at $ 0.08/Kwh, which is, alone, bigger than the current sale price $ 0.006/scf of natural gas.

THE FORTH INSUFFICIENCY OF THE ABOVE IDENTIFIED METHODS is that there exist severe limitations in the design of the equipment with underliquid electric arcs with at least one rapidly consuming electrode. In fact, such equipment can only be designed with the carbon rod continuously fed into the vessel, or with the carbon-base electrode completely contained inside the vessel via copper rods extending to the outside of said vessel, as more appropriately described hereinafter. The former case implies serious limitations in the amount of deliverable electric current evidently because such current can only be delivered via bushing sliding along said electrode, thus implying evident limits in the number of amperes which can be delivered to the sliding carbon-base rod. The latter case requires very frequent replacements of the internally consumed electrode. Either case implies severe limitations and service problems with very frequent interruptions.

THE FIFTH INSUFFICIENCY OF THE ABOVE IDENTIFIED METHODS is that their efficiency is un-necessarily restricted, where efficiency, also called Coefficient of Performance (COP), are hereinafter defined as the ratio between the total energy produced by the equipment and the electric energy needed for its production, COP=(total energy out)/(electric energy in). In particular, it should be remembered that the total energy out of the equipment herein considered is the sum of the energy contained in the combustible gas, plus the energy contained in the heat acquired by the liquid feedstock. In fact, as established by various experimental evidence, the efficiency in the production of said combustible gases increases with the increase of the electric energy, with the increase of the operating pressure, and with other factors. In fact, the increase of the electric energy is the sole way to increase the gap for underliquid arcs. In turn, the increase of the gap implies an evident increase of the gas produced. Similarly, the increase of the pressure in the interior of the vessel implies a decrease of the bubbles of combustible gas at the location of their production, in the immediate vicinity of the arc, with consequential increase of the percentage of time in which the electric arc acts on the selected liquid feedstock, thus resulting in an increase of volume of the gas produced with the same electric power. As an example, in the transition from operation at atmospheric pressure to operations at 25 psi, the production of the combustible gas in the previous example of an electric arc operated by a 50 Kwh power unit and 1 inch carbon electrodes increases from 500 scf/h at atmospheric pressure operation to 700 scf/h at 25 psi, namely, with an increased efficiency of 40%. The operation of the same equipment at 150 psi implies the increase of the production from 500 scf of combustible gas at atmospheric pressure to 1,000 scf, resulting in an increase of efficiency of 200%. The inability of delivering large currents via sliding contacts on carbon-base rods has been pointed out above, resulting in a consequential limitation of the efficiency. Similarly, it is evident that the continuous feeding of carbon rods into the vessel prevents the achievement of any operating pressure other than atmospheric pressure due to notorious inability to achieve a good seal around a carbon rod as well as mandatory safety restrictions in the event of leakage of a combustible gas near the operator. The above restriction to operate the equipment at atmospheric pressure then implies an un-necessary limitation.

THE SIXTH INSUFFICIENCY OF THE ABOVE IDENTIFIED METHODS is that they are unable to control the chemical composition of the resulting combustible gases, except the fact that the species is composed by the new magnecules discovered by Santilli (see the above quoted monograph and literature quoted therein). This is an evident consequence of the fact that, irrespective of the selected feedstock, the laws of nature establish that the resulting combustible gas is essentially composed by 50% hydrogen atoms, 25% carbon atoms and 25% oxygen atoms in various valence, magnetic and other bonds which compose Santilli magnecules. In turn, this implies the inability of producing a combustible gas which is rich in hydrogen or in oxygen, as desired by particular applications.

THE SEVENTH INSUFFICIENCY OF THE ABOVE IDENTIFIED METHODS is that they cannot use oil as the liquid feedstock for the production of a clean combustible gas via a submerged electric arc. This is due to the fact that oils generally contain no oxygen, since oils have the general chemical structure CnH2n+2 where, as well known examples, for n=13 and 2n+2=17, we have light gasoil; for n=18 and 2n+2=25 we have heavy gasoil; and for n=26 and 2n+2=34 we have motor oil. The absence of oxygen in the process then implies that the plasma is solely composed by ionized H and C atoms without any O contribution. In turn, said H and C atoms can only combine into gaseous forms of heavy hydrocarbons, resulting in a combustible fuel which is highly pollutant and positively not recommendable for actual use.

THE EIGHT INSUFFICIENCY OF THE ABOVE IDENTIFIED METHODS is that, even when hydrocarbons produced from oil as feedstock are desired, oils cannot be used as feedstock because they create carbon composites around both electrodes in such a large amount to halt operations of the equipment in a matter of minutes. For instance, the use of oil in a vessel operated by a 50 Kwh power unit creates about one pound of carbon deposits per minute around the two electrodes. Rather than consuming, the electrodes are in this way rapidly enlarged in size, thus reaching the halting of the operation in about five minutes depending on the type of oil selected as feedstock. This carbon build-up around the electrodes is due to a variety of reasons, including the excess of carbon exposed to the electric arc originating from both the oils feedstock and the carbon-base electrodes. Such excess carbon cannot evidently be used to create heavy hydrocarbons and, therefore, accumulates at the tip of the electrodes. Moreover, there is the additional baking of the oil around the incandescent tips of the electrodes, as well as other events all contributing to additional accumulation of carbon deposits at the tips of the electrodes.

THE NINTH INSUFFICIENCY OF THE ABOVE IDENTIFIED METHODS is that even when their efficiency is over-unity, they are not “self-sustaining,”, that is, the equipment is not capable of producing its own electric energy and then remain with a usable energy excess. For instance, the above described equipment with 50 Kwh of power unit produces 500 scf of combustible gas at atmospheric pressure, which correspond to 400,000 BTU/h at an average of 800 BTU/scf, plus 100,000 BTU/h of heat acquired by the liquid feedstock. This implies a total of 500,000 BTU/h of energy output while the electrical energy input is 50,000 W/h×3.42=171,000 BTU/h. Therefore the efficiency is indeed over-unity since it has the value COP=500,000 BTU/170,000 BTU=2.94. Nevertheless, such over-unity in energy production is not capable of producing the electric energy needed for the operation of the equipment and, as such, the method here considered is not self-sustaining. This is due to the fact that the efficiency of electric generators is notoriously very low and in the range of ⅓, namely, the production of one unit of electric energy generally require three units of energy. Since the over-unity is less than 3, after taking into account various dispersions, e.g., in the heat, the methods here considered are clearly non-self-sustaining.

The main scope of this invention is that of resolving all the above major insufficiencies of the indicated methods for the self-sustaining over-unity production of clean combustible gases via nonconsumable carbon-base or metal-base electrodes.

This invention, which is more fully described hereinafter, relates to the supplying into the submerged electric arc a substance containing the element which is missing for any given feedstock in order to achieve such a mixture of mostly ionized H, C and O atoms in the arc plasma to contain equal moles of C and O as necessary to create CO and moles of H2, irrespective of whether the number of moles of H2 is larger, equal or smaller than that of CO, plus a desired excess of H or O. The supplying into the electric arc of said missing element renders the electrodes essentially nonconsumable, thus resolving the insufficiencies of pre-existing methods numbers one, two and six as identified above. In turn, the achievement of electrodes with long life permits the construction of equipment operating with large powers and pressures, with a dramatic increase of the efficiency and the consequential achievement of self-sustainment as defined plus an excess of usable energy, thus resolving the remaining insufficiencies three, four, five, seven, eight and nine of pre-existing methods identified above.

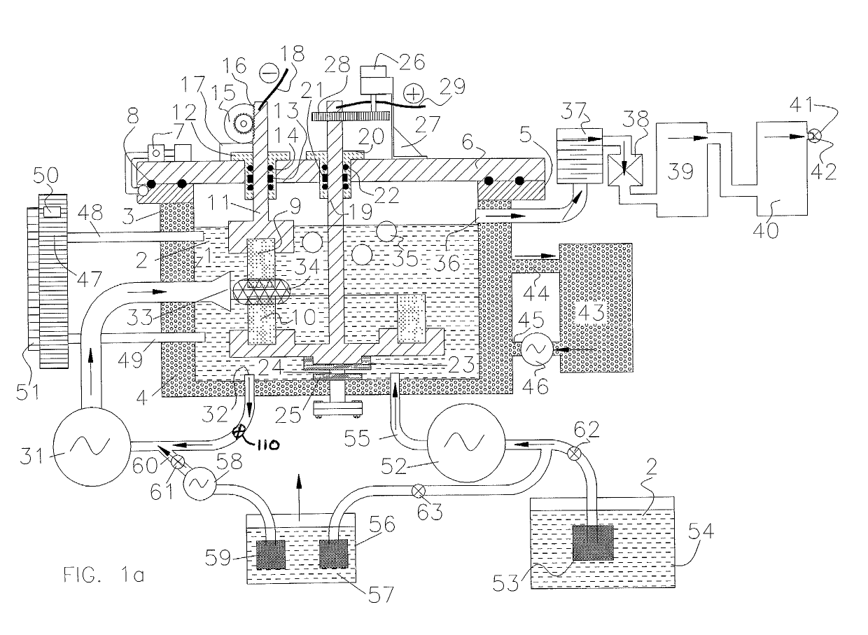

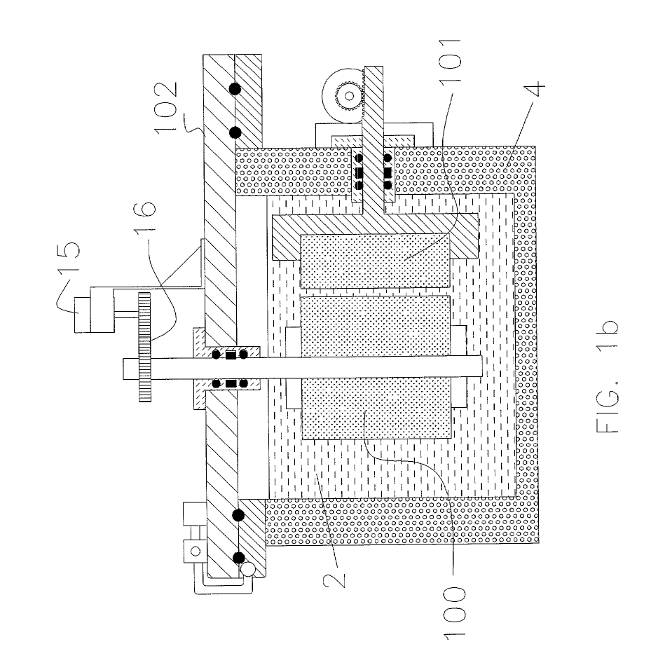

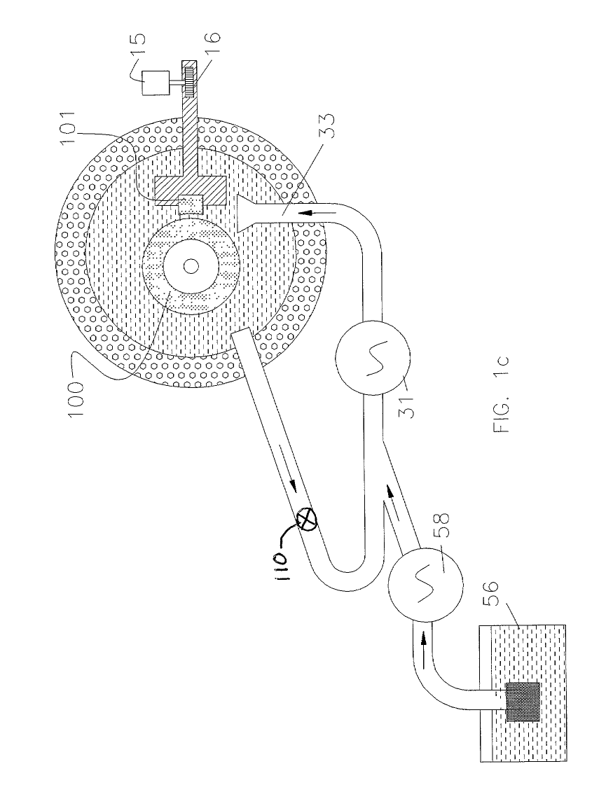

FIG. 1A is a diagrammatic schematic representative of a preferred typical application of equipment used in the invention;

FIG. 1B is a diagrammatic schematic side view of a another typical application of equipment used in the invention; and

FIG. 1C is a diagrammatic schematic top view depicting the equipment of FIG. 1B.

As mentioned above, this invention, which is more fully described hereinafter, relates to the supplying into the submerged electric arc a substance containing the element which is missing for any given feedstock in order to achieve such a mixture of mostly ionized H, C and O atoms in the arc plasma to contain equal moles of C and O as necessary to create CO and moles of H2, irrespective of whether the number of moles of H2 is larger, equal or smaller than that of CO, plus a desired excess of H or O. The supplying into the electric arc of said missing element renders the electrodes essentially nonconsumable, thus resolving the insufficiencies of pre-existing methods numbers one, two and six as identified above. In turn, the achievement of electrodes with long life permits the construction of equipment operating with large powers and pressures, with a dramatic increase of the efficiency and the consequential achievement of self-sustainment as defined plus an excess of usable energy, thus resolving the remaining insufficiencies three, four, five, seven, eight and nine of pre-existing methods identified above.

The main novelties of this invention can be summarized as follows.

A method for the production of a clean burning combustible gas plus usable heat from an oil-base oxygen-deficient feedstock comprising:

providing a pressure resistant vessel containing an oil-base oxygen-deficient feedstock, the vessel having a submerged electric arc between carbon-base electrodes;

causing a mixture of said oxygen-deficient feedstock and an oxygen-rich additive to flow through said submerged electric arc;

wherein oxygen is supplied to the electric arc to achieve a mixture of mostly ionized H, C and O atoms in such to obtain equal moles of C and O as necessary to create CO and moles of H2 all elements bonded into magnecular clusters, irrespective of whether the number of moles of H2 is larger, equal or smaller than that of CO;

wherein the flowing of the oxygen-rich additive through the electric arc prevents a rapid consumption of the carbon-base electrodes;

wherein the produced clean burning combustible gas bubbles to the surface of the liquid feedstock where it is collected for uses;

wherein the thermochemical reactions producing said combustible gas create a heat acquired by said liquid feedstocks and usable via heat exchangers;

wherein the sum of the energy contained in the combustible gas and the energy contained in usable heat is bigger than the energy needed for the self-generation of the electricity required for the operation of the equipment.

A method as above described wherein only a portion of the output energy is used to produce the electricity needed for the self-generation of electricity, resulting in an environmentally acceptable production of a clean combustible gas without use of external energy sources.

A method as above described wherein the output energy is completely used to produce electric energy, resulting in an environmentally clean production of usable electric energy in excess to that needed for the self-generation of electricity.

A method for the production of a clean burning combustible gas plus heat from a water-base carbon-deficient feedstock comprising:

providing a pressure resistant vessel containing a water-base carbon-deficient feedstock, the vessel having a submerged electric arc between carbon-base electrodes;

causing a mixture of said carbon-deficient feedstock and a carbon-rich additive to flow through said submerged electric arc;

wherein carbon is supplied to the electric arc to achieve a mixture of mostly ionized H, C and O atoms in such to obtain equal moles of C and O as necessary to create CO and moles of H2 all elements bonded into magnecular clusters, irrespective of whether the number of moles of H2 is larger, equal or smaller than that of CO;

wherein the flowing of the carbon-rich additive through the electric arc prevents a rapid consumption of the carbon-base electrodes;

wherein the produced clean burning combustible gas bubbles to the surface of the liquid feedstock where it is collected for uses;

wherein the thermochemical reactions producing said combustible gas create a heat acquired by said liquid feedstocks and usable via heat exchangers;

wherein the sum of the energy contained in the combustible gas and the energy contained in usable heat is bigger than the energy needed for the self-generation of the electricity required for the operation of the equipment.

A method as above described wherein only a portion of the output energy is used to produce the electricity needed for the self-generation of electricity, resulting in an environmentally clean production of a clean combustible gas without any use of external energy sources.

A method as above described wherein the output energy is completely used to produce electric energy, resulting in an environmentally clean production of usable electric energy in excess to that needed for the self-generation of electricity.

A method for the production of a clean burning combustible gas plus heat from a liquid feedstock comprising:

providing a pressure resistant vessel containing a liquid feedstock, the vessel having a submerged electric arc between carbon-base electrodes;

causing a hydrogen-rich additive to be flown through the electric arc;

wherein a hydrogen content of said combustible gas is increased to a desired percentage by the mixing of the feedstock and hydrogen-rich additive to achieve a mixture of mostly ionized H, C and O atoms in an arc plasma and to obtain equal moles of C and O as necessary to create CO and moles of H2, irrespective of whether the number of moles of H2 is larger, equal or smaller than that of CO, all elements being bonded into magnecular clusters;

wherein the flowing of the hydrogen-rich additive through the electric arc prevents a rapid consumption of the carbon-base electrodes;

wherein the produced clean burning combustible gas bubbles to the surface of the liquid feedstock where it is collected for uses;

wherein the thermochemical reactions producing said combustible gas create a heat acquired by said liquid feedstock and usable via heat exchangers;

wherein the sum of the energy contained in the combustible gas and the energy contained in usable heat is bigger than the energy needed for the self-generation of the electricity required for the operation of the equipment.

A method as above described wherein only a portion of the output energy is used to produce the electricity needed for the self-generation of electricity, resulting in an environmentally clean production of a clean combustible gas without any use of external energy sources.

A method as above described wherein the output energy is completely used to produce electric energy, resulting in an environmentally clean production of usable electric energy in excess to that needed for the self-generation of electricity.

A method for the production a clean burning combustible gas plus heat from a liquid feedstock comprising:

providing a pressure resistant vessel containing a liquid feedstock, the vessel having a submerged electric arc between carbon-base electrodes; and

causing an oxygen-rich additive to be flown through the electric arc;

wherein an oxygen content of said combustible gas is increased to a desired percentage by the mixing of the feedstock and oxygen-rich additive to achieve a mixture of mostly ionized H, C and O atoms in an arc plasma and to obtain equal moles of C and O as necessary to create CO, plus moles of O and moles of H2 all bonded into magnecular clusters, irrespective of whether the number of moles of H2 is larger, equal or smaller than that of CO, and

wherein the flowing of the oxygen-rich additive through the electric arc prevents a rapid consumption of the carbon-base electrodes;

wherein the produced clean burning combustible gas bubbles to the surface of the liquid feedstock where it is collected for uses;

wherein the thermochemical reactions producing said combustible gas create a heat acquired by said liquid feedstock and usable via heat exchangers;

wherein the sum of the energy contained in the combustible gas and the energy contained in usable heat is bigger than the energy needed for the self-generation of the electricity required for the operation of the equipment.

A method as above described wherein only a portion of the output energy is used to produce the electricity needed for the self-generation of electricity, resulting in an environmentally clean production of a clean combustible gas without any use of external energy sources.

A method as above described wherein the output energy is completely used to produce electric energy, resulting in an environmentally clean production of usable electric energy in excess to that needed for the self-generation of electricity.

A method for the production of a clean burning combustible gas plus heat from a liquid feedstock comprising:

providing a pressure resistant vessel containing a liquid feedstock, the vessel having a submerged electric arc between carbon-base electrodes;

wherein a chemical composition of a produced combustible gas can be predetermined by an addition of an additive rich in a desired substance, said additive being caused to be flown through the electric arc;

wherein the addition of the additive to the feedstock achieves the desired combustible gas with a magnecular structure;

wherein the flowing of the additive through the electric arc prevents a rapid consumption of the carbon-base electrodes;

wherein the produced clean burning combustible gas bubbles to the surface of the liquid feedstock where it is collected for uses;

wherein the thermochemical reactions producing said combustible gas create a heat acquired by said liquid feedstock and usable via heat exchangers;

wherein the sum of the energy contained in the combustible gas and the energy contained in usable heat is bigger than the energy needed for the self-generation of the electricity required for the operation of the equipment.

A method as above described wherein only a portion of the output energy is used to produce the electricity needed for the self-generation of electricity, resulting in an environmentally clean production of a clean combustible gas without any use of external energy sources.

A method as above described wherein the output energy is completely used to produce electric energy, resulting in an environmentally clean production of usable electric energy in excess to that needed for the self-generation of electricity.

A method for the production of a clean burning combustible gas from a feedstock comprising:

providing a pressure resistant vessel containing a feedstock, the vessel having a plasma created by an electric arc between electrodes,

wherein a chemical composition of a produced combustible gas can be predetermined by flowing an additive rich in a desired substance through the plasma created by the electric arc, and

wherein the flowing of the additive through the plasma achieves a mixture of mostly ionized H, C and O atoms in the plasma to obtain equal moles of C and O as necessary to create CO and moles of H2, irrespective of whether the number of moles of H2 is larger, equal or smaller than that of CO;

Wherein the combustible gas produced is partially recycled through the electric arc to increase the production of heat acquired by the liquid feedstock.

A method as above described wherein only a portion of the output energy is used to produce the electricity needed for the self-generation of electricity, resulting in an environmentally clean production of a clean combustible gas without any use of external energy sources.

A method as above described wherein the output energy is completely used to produce electric energy, resulting in an environmentally clean production of usable electric energy in excess to that needed for the self-generation of electricity.

We now pass to a more detailed description of this invention.

Suppose that the feedstock is oil C16H34 without any oxygen content, in which case, as indicated earlier, the arc plasma is essentially composed of mostly ionized H and C atoms plus possible impurities here irrelevant, resulting in a highly polluting combustible fuel composed of heavy hydrocarbons. This invention resolves such a grave problem by injecting into the arc plasma a substance which is oxygen rich, hereinafter called oxygen-rich “additive,” irrespective of whether said oxygen-rich additive is solid, liquid or gas.

A representative, but not limiting example for the injection into the electric arc of oxygen rich additives when the latter is selected to be in the liquid state, is water, because water is vaporized and then decomposed by the arc, thus providing the oxygen needed for the appropriate thermochemical reactions in the arc plasmas. In particular, this invention requires about 33% water and 73% oil feedstock to achieve the above indicated equal number of C and O in the arc plasma, when considering all construction and operational aspects, including dispersions.

Extensive tests have established that, in the latter case, the combustible gas is indeed clean and essentially composed of magnecular structures of hydrogen and carbon monoxide in single, double or triple valence bonds. The same extensive tests have also established that the consumption of the carbon-base electrodes is grossly reduced, thus substantially decreasing the production costs of the clean combustible gas.

An additional advantage for using ordinary water as oxygen-rich additive is that part of it evaporates under the high temperature of the electric arc via the known violent transition of state from liquid to vapor, in which case the latter cleans the electrodes from the oil baked around the incandescent electrode tips.

For the case of gaseous substances to be injected into the arc whenever oil is used as feedstock, a representative, yet not limiting example, is the injection of the conventional oxygen gas which yields results similar to those of water.

A representative example of an oxygen-rich additive in the solid state is the injection of bismuth oxides such as Bi2O3 or Bi2O5 in an earthen form or synthetically produced powdery form. Extensive tests have established that, in this case, the electric arc decomposes the bismouth oxide into Bi and O atoms; the O atoms are used for the creation of the combustible gas, while Bi precipitates at the bottom of the reactor for periodical collection.

Consider now the case of a water-base feedstock, such as ordinary water, antifreeze waste, de-icing liquid waste, liquid animal waste, etc. In all these cases, carbon is either entirely missing from the liquid feedstock as it is the case for water, or it is contained in insufficient amount as it is the case for liquid animal waste. As a result of this insufficiency, the carbon-base electrodes are consumed by the electric arc, by providing in this way the carbon needed for the production of a clean combustible gas. In the latter cases, this invention consists in supplying directly into the electric arc a carbon-rich additive irrespective of whether solid, liquid or gaseous.

Consider, for instance, the processing of liquid animal waste. In this case extensive tests have established that the feeding directly into the electric arc of an oil-base additive does indeed prevent the rapid consumption of the electrodes, thus permitting the design of equipment with long life and low operating costs. Similar results are reached in supplying directly into the electric arc solid carbon or ordinary coal in the form of powder, or in supplying a carbon-rich gas, such as methane.

Said oxygen-rich or carbon-rich additives can be supplied into the electric arc in a variety of ways. That preferred in this invention consists in forcing the flow of a liquid additive through the electric arc via a pump as more particularly described below. An alternative method is that of forcing the flow through the electric arc via a pump of a mixture of the feedstock and the needed additive.

The optimization of this invention can be achieved by controlling the flow of the additive via an ordinary valve. Since the carbon-base rods do not consume appreciably for this invention, they can be fed into the vessel via copper rods protruding to the outside for the initiation and control of the arc. As a consequence, the consumption of the carbon-base electrodes is fully visible and measurable in the outside of all equipment. The flow of the additive can, therefore, be increased or decreased until achieving a flow for which there is no appreciable consumption of the carbon-base electrodes.

An alternative means for operating this invention is to add the needed oxygen-rich or carbon-rich substance to the liquid feedstock in the needed percentages generally consisting of 67% feedstock and 33% additive, thoroughly mix the two substances until reaching a homogeneous suspension, and then to activate the underliquid electric arc.

As an illustration, the processing of water-base liquid feedstock into a clean combustible gas can be done with a major reduction of the consumption of the carbon electrodes by adding to said liquid feedstock coal reduced to a powdery form and then mixing the two substances to the point of reaching a homogeneous suspension of carbon in the water-base liquid feedstock. This permits the presence of additional carbon under the electric arc in the needed amount, thus implying a major reduction of the consumption of the carbon-base electrodes.

The flowing of the additive or of a mixture of feedstock and additive has a crucial importance for efficiency. In fact, such a flow prevents CO to be oxidized into CO2 while jointly preventing that H and O recombine into H2O, with a consequential evident increase of the volume of combustible gas produced for the same electric power.

The new chemical species of magnecules composing the combustible gases permits the achievement of a density and energy content much greater than the corresponding combustible gas with conventional molecular composition. As a result, the special version of combustible gas primarily composed of hydrogen with a minor component of C and O in the weak single or double valence bonds typical of magnecules is particularly interesting, e.g., in replacement of hydrogen fuels for rockets. In fact, such a hydrogen rich combustible gas with three times the energy content of the conventional hydrogen would imply an evident reduction of the weight of rocket boosters, as well as other advantages, such as reduction of costs in liquefaction.

This invention also permits the achievement for the first time of such a hydrogen rich combustible gas which can be merely achieved by adding to the oxygen-rich or carbon-rich substance any solid, liquid of gas which is very rich in hydrogen.

Thanks again to the magnecular structure, the above methods also permit the achievement of a type of combustible gas with excess oxygen, resulting in a gas which is particularly significant to replenish the oxygen currently depleted by the combustion of fossil fuels. It should be noted that such an excess oxygen is not free in the structure of the magnecules, because in that case the resulting gas would be dangerous due to the joint presence of hydrogen. In fact, said excess of oxygen is trapped inside the magnecular clusters, by being released only at the time of the combustion, thus achieving a stable and safe oxygen rich fuel.

As a result, this invention permits the achievement of a clean burning combustible gas with the pre-set chemical structure depending on uses and applications.

This invention also contemplates the use of metal-base electrodes, such as tungsten electrodes, which are evidently preferable to nonconsumable carbon electrodes particularly in all applications with limited electric power, e.g., consumer applications.

It should be pointed out that this invention applies also for the case in which the electric arc occurs within a gaseous, rather than a liquid medium. Whether starting from a liquid or a gaseous feedstock, the electric arc creates essentially the same type of plasma which, for the purpose of producing a clean burning combustible gas, should be formed by equal amounts of C and O plus H. It is then evident that, whenever the gaseous feedstock is deficient in one given element to provide said clean combustible gas, the supply as per this invention into the electric arc plasma of a substance rich in the missing element resolves the problem. As a result, this invention is applicable for both liquid and gaseous feedstocks, with the understanding that the efficiency in the use of liquid feedstock is dramatically bigger than that for the use of gaseous feedstock.

The energy balance of underliquid electric arcs has been studied in detail in the above mentioned monograph by R. M. Santilli herein attached in copy, see, in particular, Chapters 7 and 8. These studies have established that the thermochemical reactions based on the elements contained in water, H and O, plus C from the carbon-base electrodes release such energy to permit a quantitative scientific explanation of the over-unity efficiency of the methods herein considered. In fact, the recombination of H and O into H2O releases 115 Kcal/mole, the combination of C and O into CO releases 255 Kcal/mole, the combination of CO and O into CO2 releases 68 Kcal/mole, etc. The same studies herein quoted have established that the over-unity of the process increases when considering oil-base liquids as feedstock while power and all other factors are considered the same. In summary, the over-unity value (energy in gas+heat acquired by feedstock)/(electric energy for operation)>1 is entirely explained via thermochemical reactions without any need to assume the participation of nuclear reactions. Recall than in a typical reactor such as that according to U.S. Pat. No. 6,183,604 to R. M. Santilli with 50 Kwh power unit operating at atmospheric pressure, one unit of electric energy generally produce three unit of energy in the combustible gas plus one unit of heat, resulting in an over-unity of 4. The molecular nature of the process then explains the complete lack of radiations emanating from the process, and its consequential safety for operators and for the environment.

The use of the above quoted studies then readily permit the increase of the heat acquired by the liquid feedstock, whenever such increased heat is needed or otherwise useful, e.g., for electric generation as specified below. Recall that the flowing of an additive through a submerged electric arc prevents the recombination of H and O into H2O as well as that of CO into CO2, thus maximizing the production of the combustible gas, rather than the heat. If an increase of heat is needed for specific applications, e.g., to power a turbine, the latter can be readily achieved in a variety of way, the simplest one being the recirculation of the combustible gas produced through the electric arc, with consequential additional thermochemical reactions H+H→H2+115 Kcal/mole and CO+(O2)/2→CO2+68 Kcal/mole. In view of these large amount of released heat, the desired amount in the increased energy acquired by the liquid feedstock is then educed to a control of the flow of the combustible gas through the electric arc.

Similarly, the flowing through the arc of an oxygen-rich substance for an oxygen deficient feedstock or the flowing through the arc of a hydrogen rich substance for a hydrogen deficient feedstock automatically imply an increase of the latter thermochemical reactions with consequential increased production of heat.

We are now in a position to specify the most important feature of this invention, the achievement for the first time since the discovery of nuclear reactors, of a method which is, not only over-unity, but also self-sustaining with a significant amount of excess energy left available for utilization.

The main reasons for the achievement of the indicated self-sustaining character are: 1) the capability to deliver large electric currents to the electrodes now permitted by their shaft being of copper; 2) The capability to operate the equipment at high pressure; and 3) the capability to increase the heat acquired by the liquid feedstock. Each of these three advances imply an increase of the efficiency. When all three increases are combined, a large excess of usable energy over that needed for self-generation results.

As a specific example, consider the above case of a reactor operating at atmospheric pressure with 50 Kwh. As noted earlier, this implies the use of 100 W/scf=342 BTU/scf as measured at the grid. Nevertheless, AC-DC converters generally have 75% efficiency which means that 25 W out of 100 W are lost in said conversion, while the electric arc only requires 75 W/scf=256 BTU/scf. As also indicated earlier, when operated at atmospheric pressure, the above equipment produces 500 scf/h of combustible gas corresponding to about 400,000 BTU/h, plus about 100,000 BTU of usable heat acquired by the feedstock. This results in an over-unity of (400,000+100,000) BTU/170,000 BTU=2.99, thus being insufficient for self-generation of electricity because, as indicated earlier, the efficiency of electric generators is about ⅓.

Consider now the same equipment but constructed according to the method of this invention, which implies the delivery of 250 Kwh, operation at 150 psi, and recirculation of the combustible gas through the electric arc to increase the heat produced. In this case 250 Kwh=850,000 BTU/h of electricity produce 5,000 scf/h=4,500,000 BTU/h of combustible gas, plus about 2,000,000 BTU/h of heat, resulting in the over-unity (4,500,000+2,000,000) BTU/850,000 BTU=7.6 which is amply sufficient for self-generation of electricity, e.g., via a turbine which is partially powered by the combustible gas and partially powered by steam originating from the cooling of the equipment. In fact, on the total 6,500,000 BTU/h only 3×850,000 BTU=2,550,000 BTU are needed for the generation of the AC current used by the AC-DC converter, thus remaining with 3,450,000 BTU/h of usable energy.

Note however that in the above set up there is no need to generate AC current and then convert it into the DC current of the electric arc, because the electric generator can directly produce the needed DC current, with a consequential increase of the efficiency of 25%, namely, the energy lost in the AC-DC conversion.

Therefore, the use of a turbine or other AC electric generator is recommendable when the method of this invention is used for a new renewable clean source of electricity. In this case, the entirety of the output energy is used for the production of AC current, of which part is used for the self-generation of electricity and the remaining electricity is released into the grid.

On the contrary, the use of a DC turbine or other generator is recommendable when the method of this invention is used for the production of a combustible gas, in which case only the total amount of heat is used for the self-generation of electricity jointly with the minimal amount of the produced combustible gas, while the residual combustible gas remains available for various uses.

In addition, it should be indicated that the electric arc of this invention can also be powered by an AC current which is particularly efficient for the case of oil-base feedstocks.

A first preferred embodiment of the equipment related to this invention is depicted in FIG. 1A. An internal metal vessel 1 with the approximate cylindrical shape of about three feet in diameter and five feet in height and pressure resistant walls of ¼ inch thick is substantially but not entirely filled up with a liquid feedstock 2. The metal vessel 1 is surrounded in its cylindrical and lower parts by an external metal vessel 3 of essentially the same shape as that of vessel 1 plus 3 inches of increase dimensions which are filled up with a coolant 4. Both internal vessel 1 and external vessel 3 are sealed by a top metal ring 5 of approximately 2 inches in thickness and a cylindrical overhang of about 1 inch. The top portion of the equipment is completed by a metal lid 6 of approximately 1 inch thickness which is compressed against ring 5 by manually operated clamps 7 and ¼ inch o-rings 8.

The interior of the equipment contains two carbon-base electrodes, e.g., produced from ordinary coal, the anode 9 with negative sign in a solid cylindrical shape of about 5 inches in outside diameter and 5 inches in length which acts vertically edgewise on the top of a hollow cylindrically shaped, positively charged cathode 10 of the same thickness as that of the anode 9, an outside diameter of approximately two feet and a height of about 5 inches.

Anode 9 is supported by copper shaft 11 of approximately 3 inches in diameter which terminates with a copper holder capable holding under pressure anode 9 while leaving about 3 inches of axially usable carbon. Copper shaft 11 is set in such a fashion to be able to move vertically upward or downward via bushing 12 and internal linear bearings 13 and seals 14. Electric motor 15 ends with a gear engaging rake 16 supported by base 17 solidly connected with lid 6, e.g., via welded brackets. Said motor 15 then permits the movement of copper shaft 11 upwardly or downwardly depending on the need of the electric arc as described below. Copper shaft 11 ends with a terminal with cables 18 carrying the negative from a DC power generator of about 250 Kwh.

Cathode 10 is supported by a second copper shaft 19 also of about 3 inches in diameter which ends with a copper holder having the negative shape of said cathode 10 and capable of holding the latter under pressure while releasing at least 3 inches of axially usable carbon-base cathode. Copper shaft 19 penetrates within lid 6 via bushing 20 with linear bearing 21 and seal 22.

The cylindrical shaped holder at the end of copper shaft 19 is supported at the bottom of vessel 1 by a non-conducting bases 23 and 25, e.g., in phenolic, interconnected by bearing 24 permitting the rotation of said cathode 10. An electric motor 26 supported by base 27 solidly fastened to lid 6, e.g., via welding, controls the rotation of cathode 10 via gear 28. The cathode set up ends with a housing suitable to be connected with cables 29 from a DC generator of 250 Kwh (not shown in the figure) for the delivery of the positive polarity.

An underliquid DC electric arc can be created in between anode 9 and cathode 10 via automatic means (not shown in the figure) acting on electric motor 15 which initiates the arc via actual shorting of anode 9 on cathode 10 and then retracting immediately thereafter anode 9 to the operating arc gap which, for 250 Kwh is of about ½ inch length at about 70 V. An automatic micrometric control of the position of anode 9 conducted every 50 milliseconds then permits a stable electric arc with an essentially constant voltage. Jointly, but independently with the above initiation and control of the electric arc, electric motor 26 rotates cathode 10 under anode 9 at the rate of 1/10 revolution per minute.

The reason for the above embodiment of anode and cathode is that, as well known, the anode does not generally consume since it releases the electrons of the DC current, thus permitting its selection in dimension smaller than that of the cathode. By comparison, the cathode does generally consume because it receives the electrons of the DC current, thus achieving high incandescence at about 10,000 degrees F. For this reason, the preferred equipment described in this invention is based on the selection of a cathode with a mass of carbon much larger than that of the anode and actually computed in such a way to require their replacement at the same time. The replacement is easily and rapidly made in the embodiment herein considered due to the easy and rapid removal of the top lid 6 via the disengagement of manually operated clamps with consequential exposure of both electrodes, their rapid replacement, and consequential rapid re-insertion of lid 6 on ring 5. Needless to say, for the case of an AC operated electric arc, there is no difference in the behavior of the two electrodes.

In regard to the flow of the additive through the electric arc, this preferred equipment comprises tank 59 for the oxygen-rich or hydrogen-rich additive, pumps 31 and 58, valves 61 and 110, outlet 56 for the additive, and outlet 32 for the liquid feedstock. The first set-up of this invention requires valve 110 to be closed, in which case no liquid feedstock is flown through the electric arc, pump 58 to be closed, valve 61 to be open and pump 31 to be operative. In this case, the oxygen-rich or hydrogen rich additive in tank 59 is flown through the electric arc via outlet 33 neat the latter.

The alternative operating set-up is that both valves 61 and 110 are open and both pumps 31 and 58 are operative. In this case a mixture of the liquid feedstock and said additive is flown through the electric arc.

The operation of the above equipment is that the electric arc decomposes the mixture of liquid feedstock plus additive into its atomic constituents, subsequently ionizes the latter while evaporating the carbon of the electrodes, thus forming plasma 34 of mostly ionized H, C and O atoms at about 10,000 degrees F. The flow through the electric arc of the additive or of the mixture of feedstock and additive removes the plasma 34 immediately after its creation, by preventing in this way that H and O recombine into water or that CO is oxidized into CO2, with consequential great improvements of the environmental quality, and increase of the efficiency and decrease of operating costs.

When removed from the electric arc by the flow of the liquid feedstock 2, plasma 34 cools down in the surrounding liquid 2. Magnecules are then formed resulting in bubbles 35 of a combustible gas which reaches the surface of the liquid feedstock and then exits vessel 1 through outlet 36. Said gas then moves into tower 37 with an internal labyrinth in which residual liquids molecules carried by combustible gas are partially separated. Said gas subsequently moves into strainer 38 internally filled up with a mesh suitable for the additional removal of liquid molecules carried by the gas. The latter than passes into storage tower 39, and then through filters 40. Downstream of filters 40 is a back pressure regulator 41 which permits the setting of the operations pressure up to 150 psi. All combustible gas produced in excess of 150 psi then exits through outlet 42.

One advantage of producing a combustible gas at high pressure is evident in as much as such a production eliminates the use of compressors, since the gas is at a pressure ready for use. As an illustration, gas fueled turbine operated electric generators generally operate at about 70 psi. Therefore, the setting of back pressure regulator 41 at 70 psi permits in this case that the combustible gas produced by the equipment can directly be used to fuel said turbine without any use of a compressor.

As well known, the thermochemical reactions underlying the production of combustible gas release large amounts of heat. As a consequence, vessel 1 must be kept at constant temperature via a cooling system consisting of heat exchanger 43 in which coolant enters heat exchanger 43 through outlet 44 and exits heat exchanger 43 through inlet 45 via the use of pump 46. Extensive tests have established that the operating temperature of vessel 1 can be kept constant within the range of 300 to 400 degrees F. by properly adjusting the flow of coolant 4.

Note that two forms of energy are produced, that contained in the combustible gas, plus heat usable through the heat exchanger 43. In particular, the latter is released by a coolant at above the boiling temperature of the water. As a result of which exchanger 43 can be replaced with a turbine operating an AC/DC electric generator, which turbine can be partially fueled by the combustible gas and partially by the steam produced in the cooling of vessel 1.

When the electric generator is in AC mode, the entire energy output of the equipment is used to produced electricity, part of which is used to power a DC converter not shown in the picture for the electricity needed for the electric arc, and the remaining AC current is released into the grid. Alternatively, the electric arc can be directly powered by the AC current, resulting in bigger efficiency. When the electric generator is in DC mode, the entire heat is used for the production of electricity plus the minimal amount of combustible gas as needed for the self-generation of electricity. The remaining combustible gas is then available for various uses.

Means for the automatic refill of the processed liquid feedstock 2 can be provided, which consists of tower 47 connected via tubes 48 and 49 to vessel 1 so as to have in its interior the same level of the liquid feedstock 2 as that existing in vessel 1. Inside tower 47 there is a floater equipped with a magnet 50, which activates an array of external magnetic sensors 51. In this way the level of the liquid feedstock can be detected in the outside visually and electronically. Whenever the level of the liquid feedstock 2 is consumed by the electric arc so as to reach a minimal height of 12 inches above the arc, electronic means operated by magnetic sensors 51 (not shown in the figure) activate pump 52, which pumps liquid feedstock 2 contained in an outside tank 54 to vessel 1 via outlet 55 from tank 54, which is also the inlet for the feedstock to vessel 1. Tank 54 includes a plunger 53 connected to outlet 55. Whenever the level of liquid feedstock 2 inside vessel 1 reaches the lower edge of combustible gas outlet 36, magnetically operated sensors 51 stop the action of pump 52, thus permitting continuous operation without the refilling of the internal liquid feedstock.

As indicated in the preceding description of this invention, the above described equipment does not work when the liquid feedstock is oil and the operation with water-base liquid feedstock implies a rapid consumption of the carbon-base electrodes in such an amount that, for the above described dimension of the anode and cathode, their replacement is generally needed after eight hours of operations.

The above insufficiencies are resolved by this invention via the set-up indicated above indicated. A separate tank 56 is filled with the needed oxygen-rich or carbon-rich liquid additive 57. Pump 58 is capable of flowing liquid additive 57 through the electric arc either alone or in combination with the liquid feedstock.

The operation of the latter preferred embodiment is the following. Consider first the processing of an oil-base feedstock into a combustible gas via an underliquid arc between carbon-base electrodes 9, 10. In this case the lack of oxygen and the consequential excess carbon in the liquid imply the creation of large carbon deposits in the negatively charged anode 9 since carbon atoms become ionized, by acquiring a positive charge and being consequently attracted by the negatively charged anode. In turn, the creation of the carbon deposits implies that, in order to maintain a stable arc, anode 9 must be moved away from cathode 10 in an amount proportional to the continuous creation of carbon deposits. As indicated earlier, the resulting combustible gas is highly polluting and not usable because consisting of heavy hydrocarbons based on C and H.

While the preferred equipment is operated according to the above way, pump 58 is activated and valve 61 is opened so as to permit the injection into the flow of the water-base, oxygen-rich additive 57 contained in tank 56. A minimal flow of said additive 57 implies an immediate visible reduction of the outward motion of anode 9. On the contrary, an excessive flow of additive 57 implies that anodes 9 is consumed. The flow of additive 57 via valve 61 can then be adjusted until such a value at which anode 9 is stationary, thus implying a major reduction of the consumption of the electrodes with consequential major reduction of operating cost of the equipment down to a value, which renders the combustible gas produced cost competitive with respect to fossil fuels. Jointly, extensive tests have established that the gas produced is indeed clean burning since it is produced under the correct mixture of H, C and O atoms in the arc plasma as indicated above.

For the case of processing of water-base feedstock 2, the liquid additive 57 can be an oil-base liquid. In this case anode 9 visibly consumes whenever valve 61 is off. A minimal opening valve 61 under the action of pump 58 implies a visible reduction in the consumption of anode 9, while a large flux of additive 57 implies in this case the need to move anode 9 away from cathode 10 due to the formation of said carbon composites. An adjustment of the flow of additive 57 via valve 61 then permits again the achievement of conditions under which anode 9 is stationary with results similar to the preceding case since the two settings imply an essentially similar composition of the arc plasma even though starting from basically different feedstock 2.

An alternative way of operating the above preferred equipment without injecting the additive into the flow, thus with pump 58 off, is to close valve 62 in the means for refilling vessel 1 with feedstock 2 and open instead valve 63, thus permitting refilling pump 52 to send into vessel 1 additive 57 in the desired amount usually being of the order of 33% of feedstock 2. Flow pump 31 is then activated for at least 20 minutes with the electric arc off so as to achieve a fully homogeneous mixture of the liquid feedstock 2 and the liquid additive 57. After that, the equipment is operated with the flow, pump 31 on and arc activated. In this case the liquid additive is contained within the liquid feedstock, thus both reaching the electric arc in the proportions needed to produce combustible at a cost competitive with respect to that of fossil fuels.

The above preferred equipment is completed by a DC power unit of 250 Kwh not shown in FIG. 1A which, under an efficiency of the rectifier of the AC into the DC current of about 75%, can power the electric arc between electrodes 9 and 10 with about 3,000 A and about 65 V and an arc gap of about ½ inch. Moreover the preferred embodiment herein considered can be operated up to the pressure of 150 psi as indicated earlier. Finally, the same tests have established that the equipment herein considered can be operated at a constant temperature of about 400 degrees F.

Still another way of operating the above equipment is by forcing some of the combustible gas produced to flow through the electric arc via a simple recirculating pipes not shown in the figures. As indicated earlier, the latter feature permits a major increase of the heat produced by the thermochemical reactions underlying this method.

In another typical application of the equipment contemplated by the invention, referring to FIGS. 1B and 1C, all systems and controls are the same as those described above, the sole difference resting in the shape and positions of the electrodes. In the latter case, the positively charged cathode 100 is composed of a carbon-base cylinder of the outside diameter of about two feet and the height as long as for the desired duration of the operations prior to replacement of the electrodes, e.g., 5 inches for one 8-hours working day, 25 inches for a five day working week, etc. Anode 101 now has a rectangular shape with thickness of 5 inches, width of 5 inches and the same length as that of cathode 100.

In this case, the means for maintaining and rotating cathode 100 are the same as those of the equipment of FIG. 1A. However, the means for sustaining and moving the anode 101 are moved from the vertical position of the equipment of FIG. 1A into the horizontal position shown in FIGS. 1B and 1C.

Except for the indicated differences, all operations of the equipment of FIGS. 1B and 1C are identical to those of the equipment of FIG. 1A.

An advantage of the embodiment of FIGS. 1B and 1C over that of FIG. 1A is that the base equipment of FIGS. 1B and 1C without additive has an operation life as long as desired, while the same operative life is limited to a maximum of one 8-hours working day for the equipment of FIG. 1A.

An additional advantage of the equipment of FIGS. 1B and 1C over that of FIG. 1A is that the configuration of FIGS. 1B and 1C provides for an operating efficiency larger than that of the configuration of FIG. 1A. This is due to the fact that the electric resistance of carbon rods is about 30 times that of copper. Therefore, the more the DC current propagates within carbon rods, the smaller is the efficiency. An increase of the life of the equipment of FIG. 1A implies an increase of the length of the electrodes 9 and 120, with consequential decrease of efficiency. By comparison, an increase of the life of the equipment as in FIGS. 1B and 1C can be done by increasing the length of electrodes 100 and 101 without an increase of the travel of the DC current through the carbon which is set by the radius of cathode 100 and the width of anode 101.

Since this invention implies a substantial reduction of the consumption of the carbon-base electrodes, but not their absolute elimination, it is evident that the equipment of FIGS. 1B and 1C permit an operative life prior to the replacement of the electrodes which is a multiple of that of the equipment of FIG. 1A. Despite that, the equipment of FIG. 1A has the advantage over that of FIGS. 1B and 1C in that the lifting of the lid 6 permits the rapid exposure of both electrodes 9 and 10, while in the case of the equipment of FIGS. 1B and 1C, the lifting of the lid 102 solely permits the exposure of cathode 100, since anode 101 remains submerged in the liquid feedstock 2. The selection of the embodiment is then left to the specific application, e.g., whether light-duty, in which case the embodiment of FIG. 1A is preferable, or heavy duty, in which case the embodiment of FIGS. 1B and 1C is preferable.

Exactly the same types of preferred embodiments described above can be used for the production of magnegases which are either rich in hydrogen or rich in oxygen, which objective is achieved via hydrogen-rich or oxygen-rich additives, respectively, in addition to those needed to achieve a one-to-one ratio of C and O in the arc plasma.

The same preferred equipment can then be used for the achievement of other forms of magnegases, such as those with excess water content to prevent backfires during the combustion.

It should be understood that the preceding is merely a detailed description of one or more embodiments of this invention and that numerous changes to the disclosed embodiments can be made in accordance with the disclosure herein without departing from the spirit and scope of the invention. The preceding description, therefore, is not meant to limit the scope of the invention. Rather, the scope of the invention is to be determined only by the appended claims and their equivalents.

Now that the invention has been described,

What is claimed is:

1. A method for the production of a clean burning combustible gas plus usable heat from an oil-base oxygen-deficient feedstock comprising:
providing a pressure resistant vessel containing an oil-base oxygen-deficient feedstock, the vessel having a submerged electric arc between carbon-base electrodes; and
causing a mixture of said oxygen-deficient feedstock and an oxygen-rich additive to flow through said submerged electric arc,
wherein oxygen is supplied to the electric arc to achieve a mixture of mostly ionized H, C and O atoms and to obtain equal moles of C and O as necessary to create CO and moles of H2, irrespective of whether the number of moles of H2 is larger, equal or smaller than that of CO,
wherein the flowing of the oxygen-rich additive through the electric arc prevents a rapid consumption of the carbon-base electrodes,
wherein a produced clean burning combustible gas bubbles to the surface of the liquid feedstock where it is collected for uses,
wherein the thermochemical reactions producing said combustible gas create a heat acquired by said liquid feedstocks and usable via heat exchangers, and
wherein the sum of an energy contained in the combustible gas and an energy contained in usable heat is bigger than an energy needed for the self-generation of the electricity required for the operation of the submerged electric arc.

2. A method as per claim 1, wherein only a portion of the energy from the gas and usable heat is used to produce the electricity needed for the self-generation of the electricity required to energize the electric arc, resulting in an environmentally acceptable production of a clean combustible gas without use of external energy sources.

3. A method as per claim 1, wherein the energy from the gas and usable heat is completely used to produce electrical energy, resulting in an environmentally clean production of usable electric energy in excess to that needed for the self-generation of electricity.

4. A method for the production of a clean burning combustible gas plus heat from a water-base carbon-deficient feedstock comprising:
providing a pressure resistant vessel containing a water-base carbon-deficient feedstock, the vessel having a submerged electric arc between carbon-base electrodes; and
causing a mixture of said carbon-deficient feedstock and a carbon-rich additive to flow through said submerged electric arc,
wherein carbon is supplied to the electric arc to achieve a mixture of mostly ionized H, C and O atoms and to obtain equal moles of C and O as necessary to create CO and moles of H2, irrespective of whether the number of moles of H2 is larger, equal or smaller than that of CO,
wherein the flowing of the carbon-rich additive through the electric arc prevents a rapid consumption of the carbon-base electrodes,
wherein a produced clean burning combustible gas bubbles to the surface of the liquid feedstock where it is collected for uses,
wherein the thermochemical reactions producing said combustible gas create a heat acquired by said liquid feedstocks and usable via heat exchangers, and
wherein a sum an energy contained in the combustible gas and an energy contained in usable heat is bigger than an energy needed for the self-generation of the electricity required for the operation of the submerged electric arc.

5. A method as per claim 4, wherein only a portion of the energy from the gas and usable heat is used to produce the electricity needed for the self-generation of the electricity required to energize the electric arc, resulting in an environmentally acceptable production of a clean combustible gas without use of external energy sources.

6. A method as per claim 4, wherein the energy from the gas and usable heat is completely used to produce electrical energy, resulting in an environmentally clean production of usable electric energy in excess to that needed for the self-generation of electricity.

7. A method for the production of a clean burning combustible gas plus heat from a liquid feedstock comprising:
providing a pressure resistant vessel containing a liquid feedstock, the vessel having a submerged electric arc between carbon-base electrodes; and
causing a hydrogen-rich additive to be flown through the electric arc,
wherein a hydrogen content of said combustible gas is increased to a desired percentage by the mixing of the feedstock and hydrogen-rich additive to achieve a mixture of mostly ionized H, C and O atoms in an arc plasma and to obtain equal moles of C and O as necessary to create CO and moles of H2, irrespective of whether the number of moles of H2 is larger, equal or smaller than that of CO,
wherein the flowing of the hydrogen-rich additive through the electric arc prevents a rapid consumption of the carbon-base electrodes,
wherein a produced clean burning combustible gas bubbles to the surface of the liquid feedstock where it is collected for uses,
wherein the thermochemical reactions producing said combustible gas create a heat acquired by said liquid feedstock and usable via heat exchangers, and
wherein a sum of an energy contained in the combustible gas and an energy contained in usable heat is bigger than an energy needed for the self-generation of the electricity required for the operation of the submerged electric arc.

8. A method as per claim 7, wherein only a portion of the energy from the gas and usable heat is used to produce the electricity needed for the self-generation of the electricity required to energize the electric arc, resulting in an environmentally acceptable production of a clean combustible gas without use of external energy sources.

9. A method as per claim 7, wherein the energy from the gas and usable heat is completely used to produce electrical energy, resulting in an environmentally clean production of usable electric energy in excess to that needed for the self-generation of electricity.

10. A method for the production a clean burning combustible gas plus heat from a liquid feedstock comprising:
providing a pressure resistant vessel containing a liquid feedstock, the vessel having a submerged electric arc between carbon-base electrodes; and
causing an oxygen-rich additive to be flown through the electric arc,
wherein an oxygen content of said combustible gas is increased to a desired percentage by the mixing of the feedstock and oxygen-rich additive to achieve a mixture of mostly ionized H, C and O atoms in an arc plasma and to obtain equal moles of C and O as necessary to create CO, plus moles of O and moles of H2, irrespective of whether the number of moles of H2 is larger, equal or smaller than that of CO,
wherein the flowing of the oxygen-rich additive through the electric arc prevents a rapid consumption of the carbon-base electrodes,
wherein a produced clean burning combustible gas bubbles to the surface of the liquid feedstock where it is collected for uses,
wherein the thermochemical reactions producing said combustible gas create a heat acquired by said liquid feedstock and usable via heat exchangers,
wherein a sum of an energy contained in the combustible gas and an energy contained in usable heat is bigger than the energy needed for the self-generation of the electricity required for the operation of the submerged electric arc.

11. A method as per claim 10, wherein only a portion of the energy from the gas and usable heat is used to produce the electricity needed for the self-generation of the electricity required to energize the electric arc, resulting in an environmentally acceptable production of a clean combustible gas without use of external energy sources.

12. A method as per claim 10, wherein the energy from the gas and usable heat is completely used to produce electrical energy, resulting in an environmentally clean production of usable electric energy in excess to that needed for the self-generation of electricity.

13. A method fort the production of a clean burning combustible gas plus heat from a liquid feedstock comprising:
providing a pressure resistant vessel containing a liquid feedstock, the vessel having a submerged electric arc between carbon-base electrodes,
wherein a chemical composition of a produced combustible gas can be predetermined by an addition of an additive rich in a desired substance, said additive being caused to be flown through the electric arc,
wherein the addition of the additive to the feedstock produces a clean burning combustible gas,
wherein the flowing of the additive through the electric arc prevents a rapid consumption of the carbon-base electrodes,
wherein the produced clean burning combustible gas bubbles to the surface of the liquid feedstock where it is collected for uses,
wherein the thermochemical reactions producing said combustible gas create a heat acquired by said liquid feedstock and usable via heat exchangers, and
wherein a sum of an energy contained in the combustible gas and the energy contained in usable heat is bigger than the energy needed for the self-generation of the electricity required for the operation of the submerged electric arc.

14. A method as per claim 13, wherein only a portion of the energy from the gas and usable heat is used to produce the electricity needed for the self-generation of the electricity required to energize the electric arc, resulting in an environmentally acceptable production of a clean combustible gas without use of external energy sources.

15. A method as per claim 13, wherein the energy from the gas and usable heat is completely used to produce electrical energy, resulting in an environmentally clean production of usable electric energy in excess to that needed for the self-generation of electricity.

16. A method for the production of a clean burning combustible gas from a feedstock comprising:
providing a pressure resistant vessel containing a feedstock, the vessel having a plasma created by an electric arc between electrodes,
wherein a chemical composition of a produced combustible gas can be predetermined by flowing an additive rich in a desired substance through the plasma created by the electric arc,
wherein the flowing of the additive through the plasma achieves a mixture of mostly ionized H, C and O atoms in the plasma to obtain equal moles of C and O as necessary to create CO and moles of H2, irrespective of whether the number of moles of H2 is larger, equal or smaller than that of CO, and
wherein the combustible gas produced is partially recycled through the electric arc to increase the production of heat acquired by the liquid feedstock.

17. A method as per claim 16, wherein only a portion of the energy from the gas and usable heat is used to produce the electricity needed for the self-generation of the electricity required to energize the electric arc, resulting in an environmentally acceptable production of a clean combustible gas without use of external energy sources.

18. A method as per claim 16, wherein the energy from the gas and usable heat is completely used to produce electrical energy, resulting in an environmentally clean production of usable electric energy in excess to that needed for the self-generation of electricity.
